(19) United States
(12) Patent Application Publication
(10) Pub. No.: US 2012/0085392 A1
(43) Pub. Date: Apr. 12, 2012

(54) Method of Manufacturing Photovoltaic Roofing Tiles and Photovoltaic Roofing Tiles

(75) Inventors: Jonathan D. Albert, Philadelphia, PA (US); Abby Nessa Feinstein, Philadelphia, PA (US)

(73) Assignee: SOLAR ROOFING SYSTEMS, INC., Philadelphia, PA (US)

(21) Appl. No.: 12/919,926

(22) PCT Filed: Feb. 27, 2009
(86) PCT No.: PCT/US09/35503

§ 371 Date: Aug. 27, 2010

Related U.S. Application Data
(60) Provisional application No. 60/683,928, filed on May 23, 2005.

(51) Int. Cl. H01L 31/048; B32B 37/06; H01L 31/042; B32B 37/12; H01L 31/02; B32B 37/02; B32B 37/10

(52) U.S. Cl. 136/251; 156/212; 136/252; 136/244

(57) ABSTRACT

A method for producing a photovoltaic roofing tile includes providing an open compression tool and placing an undulated formed polymeric substrate in the open compression tool as well as placing a substantially flat photovoltaic laminate in the open compression tool proximate the substrate. Heat and pressure are applied to the photovoltaic laminate to simultaneously bond the photovoltaic laminate with the substrate and impart undulations to the photovoltaic laminate which correspond to undulations in the substrate. The heat and pressure are applied by closing the compression tool to apply heat from the compression tool to the photovoltaic laminate and to compress the photovoltaic laminate and the substrate against one another.

### CROSS-REFERENCE TO RELATED APPLICATIONS

The present application claims priority to U.S. Provisional Patent Application No. 61/031,928, which was filed on Feb. 27, 2008, and U.S. Provisional Patent Application No. 61/032,261, which was filed on Feb. 28, 2008. The contents of U.S. Provisional Patent Application Nos. 61/031,928 and 61/032,261 are incorporated herein in their entirety.

### BACKGROUND OF THE INVENTION

The present invention relates to photovoltaic roofing tiles. In particular, the present invention relates to a method of manufacturing a photovoltaic roofing tile by compression bonding photovoltaic polymeric roofing components. Also, in particular, the present invention relates to a photovoltaic roofing tile having a balanced structure.

Photovoltaics, or PV for short, is a solar power technology that uses solar cells or solar photovoltaic arrays to convert light from the sun directly into electricity. PV use in building products, such as PV roofing tiles, have now become more common place.

PV roofing tiles include a PV laminate and a PV polymeric substrate (e.g., a PV roofing component such as a tile, slate, shake, or shingle). These PV roofing components may be assembled by insert molding techniques. Insert molding is a process by which component parts are combined into a single component through the injection of thermoplastic material around the parts placed in the insert mold cavity. Insert molding exposes the PV laminate to high pressures and temperatures, such as 3,000 to 6,000 psi. Moreover, as the PV laminate is a composite material that includes various polymeric and metallic layers, the exposure of heat to the PV laminate tends to warp, expand, and/or shrink the PV laminate, potentially causing damage and wear to the PV laminate itself.

Accordingly, there is still a need for a method of manufacturing PV roofing tiles that will not damage the PV laminate during manufacturing, is simple, and cost-efficient. The present invention utilizes compression bonding to address this need.

Conventional PV roofing tiles have a PV laminate adhered to a polymeric substrate e.g., a polymeric roofing tile, to form a PV roofing tile. The PV roofing tiles, when installed on roofs, are exposed to the external environmental conditions. Such exposure can result in the PV roofing tile experiencing significant variations in temperature, such as high temperatures during direct sun exposure during the day and lower temperatures at night.

The PV laminates typically used in PV roofing tiles include PV cells that are manufactured on metal substrates such as stainless steel, aluminum, or titanium. However, a problem arises with such PV cells that are used with polymeric roofing tiles. That is, the PV cells having a metal substrate expand at a different rate, due to thermal expansion, than that of the polymeric roofing tile when exposed to cyclic temperatures due to the differences in the components' coefficient of thermal expansion (“CTE”). As a result, the PV cells experience a bending moment as metal substrates have a much lower rate of thermal expansion compared with polymeric materials in general. The bending moment ultimately leads to delamination and increased failure rates for the PV roofing tile.

There is therefore a need for a PV roofing tile having a balanced structure so that the PV cells are not detrimentally affected by cyclic or other temperature variations.

The present invention addresses the thermal expansion problem by utilizing a substrate with a reduced CTE.

Thus, the method of making the PV roofing tiles by compression bonding helps avoid damage to the PV cells caused by high temperatures and pressures of other processes. The use of a substrate with reduced CTE helps mitigate or eliminate the damage to the PV roofing tiles from cyclical changes in temperature.

### BRIEF SUMMARY OF THE INVENTION

Briefly stated, the present invention is directed to a method for producing a photovoltaic roofing tile. The method includes providing an open compression tool and placing an undulated formed polymeric substrate in the open compression tool as well as placing a substantially flat photovoltaic laminate in the open compression tool proximate the substrate. Heat and pressure are applied to the photovoltaic laminate to simultaneously bond the photovoltaic laminate with the substrate and impart undulations to the photovoltaic laminate which correspond to undulations in the substrate. The heat and pressure are applied by closing the compression tool to apply heat from the compression tool to the photovoltaic laminate and to compress the photovoltaic laminate and the substrate against one another.

In another aspect of the present invention, the substrate comprises a thermoplastic polyolefin comprising a mineral filler and having a CTE of between 25 ppm/deg C. and 50 ppm/deg C.

### BRIEF DESCRIPTION OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown.

In the drawings:

FIG. 1 is a schematic front elevational view of a compression bonding apparatus for compression bonding a PV laminate to a PV substrate;

FIG. 2 is a schematic side elevational view of a PV laminate according to a first embodiment of the present invention;

FIG. 3 is a schematic side elevational view of a PV laminate according to a second embodiment of the present invention;

FIG. 4 is a schematic top view of a PV cell layer and a tape layer structure;

FIG. 5 is a cross-sectional view of a PV roofing tile according to a third embodiment of the present invention;

FIG. 6 is a cross-sectional view of a PV roofing tile according to a fourth embodiment of the present invention;

FIG. 7 is a cross-sectional view a PV roofing tile according to a fifth embodiment of the present invention.

### DETAILED DESCRIPTION OF THE INVENTION

Certain terminology is used in the following description for convenience only and is not limiting. The words “right”, “left”, “lower” and “upper” designate directions in the drawings to which reference is made. The words “inwardly” and “outwardly” refer to directions toward and away from, respectively, the geometric center of the roofing tile and designated parts thereof. Unless specifically set forth herein, the terms “a”, “an” and “the” are not limited to one element but instead should be read as meaning “at least one”. The terminology includes the words noted above, derivatives thereof and words of similar import.

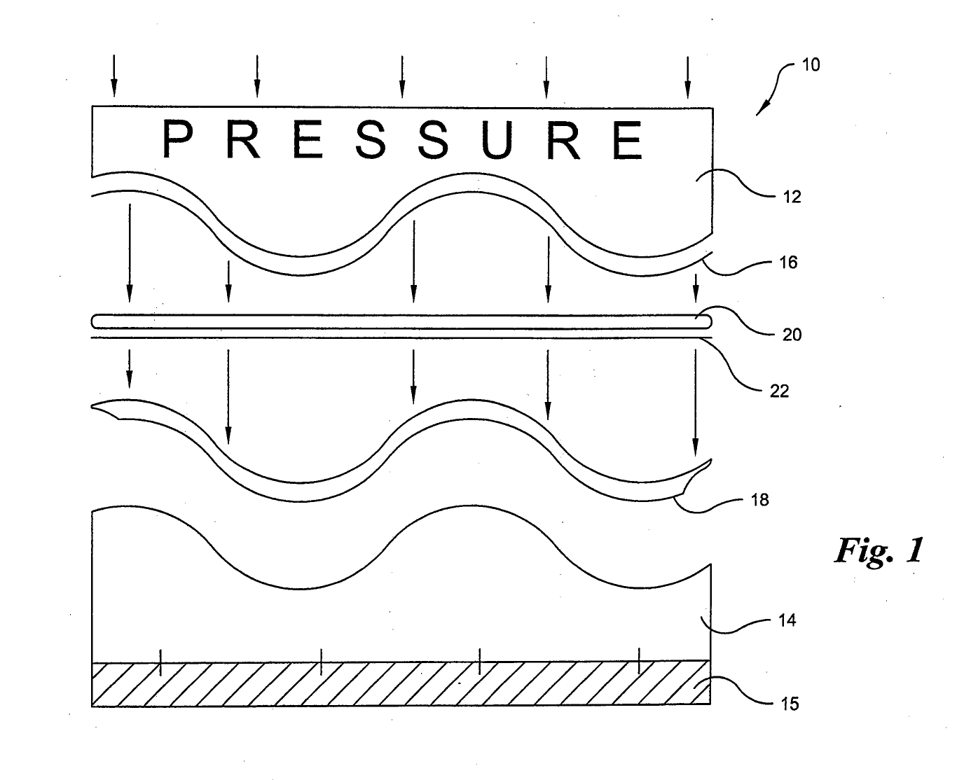

Referring to FIG. 1, the present invention is directed to a method for producing a photovoltaic roofing tile. The method is carried out by using a compression tool 10 having an upper press 12, lower press 14, and heating element 16. For example, the compression tool 10 can be a compression mold or press where the materials to be compressed are inside the mold and upper press 12 and lower press 14 (such as upper and lower dies) of the mold are closed to compress the material therein. The upper press 12 and/or lower press 14 are operably connected to a pressure source (or to respective pressure sources) that will move the upper press 12 and/or lower press 14 to close the compression tool 10. Preferably, the lower press 14 is stationary and the upper press 12 is movable during the operation of the compression tool 10, but an opposite arrangement is permissible. The upper press 12 and the lower press 14 are preferably undulated, but can have other desired shapes or surface characteristics such as particular patterns or embossing. The lower press 14 typically includes a steel base 15.

The heating element 16 shown in FIG. 1 is a surface of the tool 10 that will impart heat to the materials to be compressed and may be present as part of the upper press 12 and/or lower press 14. However, the elements which generate the heat, such as heating coils (not shown), can be inside the upper press 12 and/or lower press 14, and/or otherwise be thermally connected to upper press 12 and/or lower press 14. Alternatively, the entire process can be carried out in a furnace (not shown) where the heat generation does not have to be inside the upper press 12 and/or lower press 14 but can be a situation similar to an oven where, for example, heating coils or other heat generating elements are present, but not in contact with or connected to the material to be heated. Also, the furnace can be a convection-type furnace where hot air is supplied to provide heat to the materials being compressed.

Also referring to FIG. 1, a substrate 18 is placed inside the open compression tool 10. The substrate 18 can be substantially flat or, preferably, it can be undulated to various degrees. It can also have other shapes or surface characteristics, such as embossing (not shown). Preferably, the shape of the substrate 18 is an undulated shape which substantially matches the curvatures of the upper press 12 and/or the lower press 14, preferably both. The substrate 18 can be any conventional substrate such as a roofing tile or any other roofing component suitable for use with a photovoltaic laminate (“PV laminate”). The PV substrate 18 is preferably constructed of building code approved materials. A detailed description of the composition, function, and/or methods of manufacturing PV substrate 18 is not necessary for a complete understanding of the present embodiment, although information in this regard is provided below—it is not limiting.

Examples of substrates 18 include synthetic roofing tiles (e.g., slate, cement, ceramic), authentic slate, ceramic, or cement tiles, metal roofing, asphalt roofing, Elastocast from BASF, Bayflex from Bayer Material Science, Zytrel and/or Hytrel from Dupont, and the like. The substrate 18 can be any of a metallic, mineral, organic, polymeric, composite, or any combination thereof, or any other material readily known in the art or to be developed. It is preferred that the substrate 18 be a thermoplastic or thermoset made preferably from a polymeric and, more preferably, made of a thermoplastic polyolefin. Suitable polyolefins include polypropylene and polyethylene. Additionally, the substrate 18 preferably contains a particulate filler, preferably inorganic, such as a mineral filler. The mineral filler can be glass fibers, talc, and/or magnesium hydroxide, and is preferably talc and/or magnesium hydroxide.

The substrate 18 is preferably made by injection molding. However, it can also be made by extrusion. It can be made flat and then provided with curvatures or other shapes (such as by a press), or it can be made with the curvatures or other shapes at the time of being produced, such as by injection molding. Other suitable methods of making the substrate 18 as known by those skilled in the art are also envisaged by the present invention.

The substrate 18 is preferably primed for adhesion to the PV laminate 20. Such priming preferably includes flame treating the substrate 18. Other priming techniques such as application of chemical primers or corona treating is also contemplated in the present invention. It may even be desirable to utilize more than one priming technique with a single substrate 18.

Also, referring to FIG. 1, a PV laminate 20 is also placed in the open compression tool 10 proximate the substrate 18. Preferably, the PV laminate 20 is placed on the substrate 18 between the substrate 18 and the upper press 12. The PV laminate 20 is preferably substantially flat but can have minor curvature or other deformation, including undulation. The positioning and size of the PV laminate 20 is such that it will extend substantially over the area which will be exposed to sunlight when used on roofs. Thus, the PV laminate 20 will not be utilized in areas of the substrate 18 that will be covered from sunlight when the tile is in use. For example, if the PV roofing tiles are positioned in an overlapping relationship with other PV roofing tiles or other non-PV roofing tiles, there is no need for the PV laminate 20 to extend to the portions underneath other roofing tiles since no sun will reach those portions. Thus, preferably, the PV laminate 20 will not extend completely along the length of the substrate 18 in order to leave a space for the overlapping placement of another roofing tile. The same is true regarding the width of the substrate 18 since the overlapping relationship can be lengthwise and/or widthwise with respect to the substrate 18.

The PV laminate 20 preferably comprises an adhesive 22 thereon for bonding to the substrate 18. The adhesive 22 is preferably in the form of a layer and can be any thermoplastic compatible with the PV laminate 20 and substrate 18. Such thermoplastics include polyethylene, polypropylene, ethylene vinyl acetate copolymers, acid modified ethylene vinyl acetate copolymers, acid modified ethylene acrylate polymers, anhydride modified ethylene acrylate copolymers, anhydride modified ethylene vinyl acetate copolymers, anhydride modified high density polyethylene, anhydride modified linear low density polyethylene, anhydride modified low density polyethylene, anhydride modified polypropylene resins, maleic anhydride grafted polymers, ethylene ethyl acrylate copolymers, polyurethanes, polyesters, polyamides, vinyls, and mixtures or blends thereof. Preferably, the adhesive 22 is thermoplastic and comprises at least one selected from the group consisting of modified polypropylene and modified ethylene vinyl acetate (“EVA”), preferably anhydride modified EVA and anhydride modified polypropylene. The adhesive 22 is positioned at an end surface of the PV laminate 20 to contact the substrate 18 and bond to the substrate 18.

Preferred thermoplastic adhesives 22 for use in compression bonding photovoltaic laminates are those in which the bonding occurs above 130 degrees C., preferably 130 degrees C. to 160 degrees C. Having photovoltaic laminates bond at temperatures of 130 degrees C. to 160 degrees C. ensures that the bonds will not degrade or soften when exposed to roof top temperatures.

Alternatively, adhesives 22 applicable to the present embodiment can include curable adhesives, thermosetting adhesives, such as epoxies, polyesters, and acrylates, contact adhesives, pressure sensitive adhesives, radiation curable adhesives, and other similar adhesives readily known in the art or to be developed. Such adhesives are well known and a detailed description of their composition is not necessary for a complete understanding of the present embodiment.

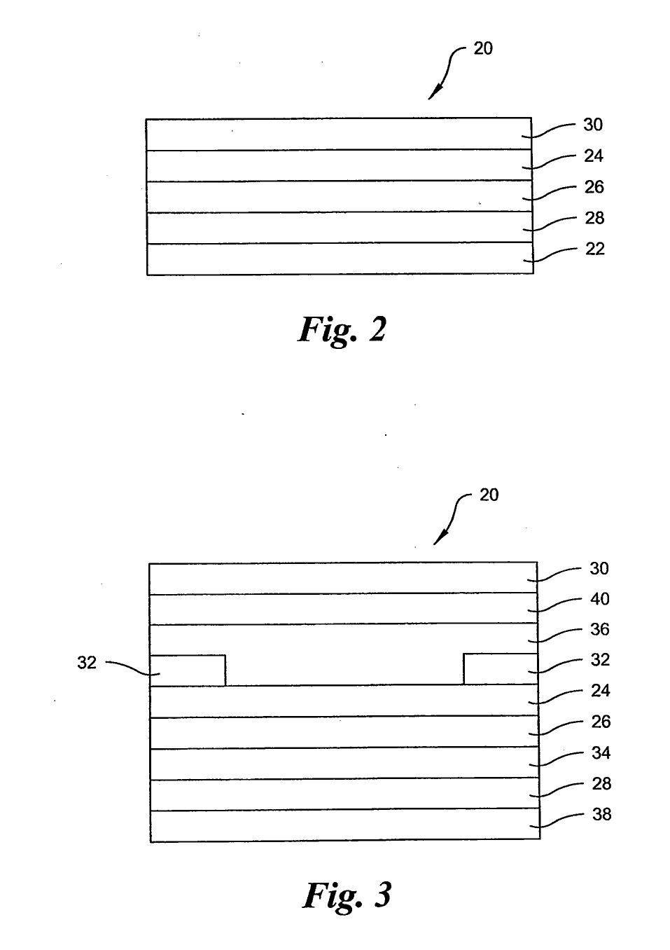

Referring to FIG. 2, the PV laminate 20 can be any conventional PV laminate 20 known and used in the art and a detailed description of such PV laminates 20 is not necessary for a complete understanding of the present embodiment. However, exemplary PV laminates 20 include one or more layers comprising PV cells 24 and circuitry. The PV cells 24 are typically on a metal substrate 26. FIG. 2 shows a layer of PV cells 24 and a layer of metal substrate 26, although additional layers can be included as part of the electronic structure of the PV laminate 20. A back sheet layer structure 28, described in more detail below, can be applied to the backside of the metal substrate 26 or to the lowest layer of the electronic structure of the PV laminate, if different than the metal substrate 26. One or more layers of the same or different materials (polymeric or otherwise) can also be present between the back sheet layer structure 28, described in more detail below, and the metal substrate 26. A transparent layer 30 is preferably applied to the top of the PV laminate 20 to allow sun exposure to the PV cells 24. One or more layers of the same or other materials can be applied between the PV cells 24 (or the topmost layer of the electronic structure of the PV laminate 20, if different than PV cells 24) and the transparent layer 30. The adhesive 22 can be applied to the back of the back sheet layer structure 28 or the adhesive 22 can be applied directly to the metal substrate 26. Additional polymeric layers can be present between the adhesive 22 and the back sheet layer structure 28 or the metal substrate 26.

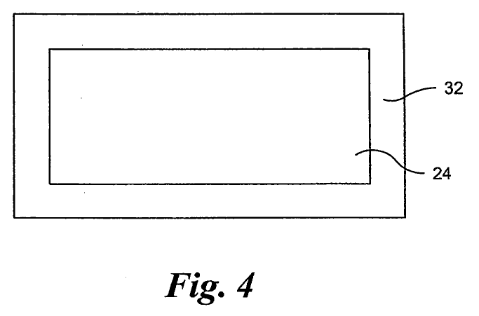

Referring to FIGS. 3 and 4, the PV laminate 20 can comprise a photovoltaic layer structure comprising photovoltaic cells 24 on a metal substrate 26, and the PV laminate 20 can also comprise at least one selected from the group consisting of a tape layer structure 32, a first encapsulation layer 34 on a first side of the photovoltaic layer structure, a second encapsulation layer 36 on a second side of the photovoltaic layer structure, a back sheet layer structure 28, a tie layer 38, a fiberglass layer 40, and a transparent layer 30. Preferably, the tape layer structure 32 is on the second side of the photovoltaic layer structure and the second encapsulation layer 36 is on the tape layer structure 32. Also, the back sheet layer structure 28 is preferably on the first encapsulation layer 34, and the tie layer 38 is preferably on the back sheet layer structure 28. Additionally, the fiberglass layer 40 is preferably on the second encapsulation layer 36 and the transparent layer 30 is preferably on the fiberglass layer 40. However, additional layers can be added between any of the aforementioned layers. Also, fewer layers than mentioned above can also be utilized. Additionally, the layers can be placed in different relative positions than as described above as long as the photovoltaic layer structure always has a layer above and below. The tape layer structure 32 is preferably positioned on the peripheral portions of the PV cells 24 such that the second encapsulation layer 36 is in contact with the tape layer structure 32 as well as the PV cells 24. However, the tape layer structure 32 can extend to a middle portion of the structure of PV cells 24.

Throughout this specification, any disclosure of a layer being in contact with or on the PV cells 24, the metal substrate 26, or the photovoltaic layer structure which includes both of them, shall mean that the layer can be in contact with the PV cells 24, the metal substrate 26, or any other layer or layers which are on the PV cells 24 or on the metal substrate 26 which one of ordinary skill in the art would know to be part of the electronic structure of the PV laminate 20, including, without limitation, conductor layers, insulation layers, metal layers, and semiconductor layers, whether coated, deposited, extruded, molded, or otherwise disposed on the PV cells 24 or on the metal substrate 26. These layers can also include any layer on which the PV cells 24 or the metal substrate 26 are fabricated on which forms part of the electronic structure of PV laminate 20. The present invention envisions a structure of primarily or wholly inorganic materials which form the PV portion, or electronic structure, of the PV laminate 20, surrounded by primarily polymeric materials to form the PV laminate 20.

The first and second encapsulation layers 34, 36 preferably comprise EVA, although other polymeric materials are also appropriate. Each of the tape layer structure 32 and the back sheet layer structure 28 preferably, independently, comprises at least a three-layered structure including a layer of EVA, a layer of PET, and a layer of EVA (not shown). Although the layers can be in any order, preferably the PET layer is the core and the EVA layers are the shell of the three-layered structure. However, the tape layer structure 32 and the back sheet layer structure 28 can, independently, comprise only single or double layers of a polymeric material such as EVA and/or PET. The tie layer 38 preferably comprises a thermoplastic hot melt and can comprise any of the same materials as the adhesive 22 mentioned above. The fiberglass layer 40 preferably comprises nonwoven fiberglass, although other nonwoven inorganic fiber structures are also appropriate. The fiberglass layer 40 is preferably sufficiently transparent to permit the appropriate electromagnetic waves from the sun to reach the PV cells for electricity generation. The transparent layer 30 preferably comprises ethylene tetrafluoroethylene (“ETFE”). Other possibilities for the transparent layer 30 are glass or other water vapor barrier layers suitable for use as a PV laminate 20 top layer, such as fluoropolymers such as ETFE. Moreover, the transparent layer 30 can be a combination of one or more transparent layers which may comprise the same or different materials. The term “layer” is intended to be interpreted broadly and may include discontinous structures, such as discontinuous layers. However, the present invention does envisage the potential use of layers which are continuous, as desired. A layer is a structure which is more extensive in a planar direction than in a thickness direction, as known by one of ordinary skill in the art.

Once both the substrate 18 and the PV laminate 20 are in the compression tool 10, the compression tool 10 closes to apply heat and/or pressure, preferably both, to the PV laminate 20 to bond the PV laminate 20 with the substrate 18 to obtain the PV roofing tile. Preferably, the operating temperature of the compression tool is 130 degrees C. to 160 degrees C., such as about 155 degrees C., and the pressure applied is 30-100 psi. The application of heat and pressure can be for a duration of about 4 minutes, although other times are possible depending on particular configurations. In contrast with typical insert molding techniques, the present invention utilizes compression bonding for assembling PV polymeric roofing components. Compression bonding involves using heat and/or pressure and time to create a bond between components. However, compared to insert molding, compression bonding typically uses lower pressures and temperatures which are less likely to damage PV cells 24 within the PV laminate 20 itself. In order to minimize or eliminate air being trapped between the laminate and the tile, vacuum is preferably applied during bonding to evacuate air from the compression tool 10 and improve the adhesion between the laminate and the tile.

Heat can be applied to one or both sides of the component being laminated, such as the PV laminate 20 and the substrate 18, by controlling the heating of the upper press 12 and/or the lower press 14. Depending upon the particular components being compression bonded, it may be advantageous to apply heat only to a single side to minimize the impact of thermal effects on the PV components (e.g., the PV laminate 20), such as the PV cells 24 and the polymeric layers. Minimizing the thermal exposure in turn minimizes the amount of thermal expansion of the polymeric components, and therefore mitigate the negative impact of thermal expansion on the overall photovoltaic roofing tile. Moreover, minimizing the amount of pressure and locations of pressure applied to the PV roofing tile further reduces the likelihood that PV cells 24 within the PV laminate 20 may be damaged during processing. The added processing control is an advantage not currently available with conventional insert molding processes.

In reference to FIG. 1, the upper press 12 and lower press 14 have undulations. If the substrate 18 also has undulations before the compression (i.e., the substrate 18 was formed with undulations or was otherwise undulated in a prior processing step), the closure of the compression tool 10 bonds the PV laminate 20 and the substrate 18 while simultaneously imparting undulations to the PV laminate 20 which correspond to undulations of the substrate 18. In this instance, preferably, the undulations in the upper press 12 and the lower press 14 will substantially match the undulations of the substrate 18. This will allow easier placement of the substrate 18 on the lower press 14, improve heat transfer, and balance the application of pressure. If the substrate 18 is substantially flat or has minor curvatures or other non-flat shape aspects, or is otherwise different than the shape of the upper press 12 and/or lower press 14, then the substrate 18 and the PV laminate 20 will be bonded to one another with simultaneous shaping of the PV laminate 20 and the substrate 18 to correspond to the shape of the upper press 12 and the lower press 14, such as to result in undulations or other shapes for the PV laminate 20 and the substrate 18.

Although it is preferred that the bonding and shaping occur simultaneously, it is possible that the bonding or shaping will occur before or after each other. It is possible to shape the substrate 18 and the PV laminate 20 with undulations separately and then bond them together. Alternatively, it is possible to bond the PV laminate 20 and the substrate 18 together and then to shape them with undulations or other patterns.

The present invention is also directed to a PV roofing tile where the substrate 18 comprises a polymeric composition having a coefficient of thermal expansion that sufficiently approaches that of the metal substrate 26 onto which the PV cells 24 are manufactured thereon. Exemplary polymeric substrates 18 include polymers with particular fillers, such as inorganic fillers like mineral fillers, as described above. Other engineered polymers specifically designed or configured to have low coefficients of thermal expansion are also possibilities. For example, the polymeric substrate 18 can be Solvay Sequel 1828 by Solvay, an engineered polyolefin having a coefficient of linear thermal expansion of 3.5×10⁻⁵ mm/mm/degrees C. (35 ppm/deg C.) from about −30 degrees C. to 80 degrees C. which sufficiently approaches the CTE of 400 stainless steel, which is 1.1×10⁻⁵ mm/mm/degrees C. (11 ppm/deg C.) so as to improve the resistance to thermal cycling of the PV roofing tile. Ideally, the polymeric substrate 18 can be any polymer composition whose coefficient of thermal expansion (“CTE”) sufficiently approaches that of the metal substrate 26 used for manufacturing PV cells 24 of the PV laminate 20 to minimize thermal cycling damage. In the present invention, although it is possible to apply the substrate 18 directly to the metal substrate 26, it is preferred that at least one other layer be present between metal substrate 26 and substrate 18. The thermal cycling in combination with different CTEs for different layers creates stress in the PV roofing tile, and layers between the substrate 18 and the metal substrate 26, such as one or more layers of EVA or other polymers, can absorb some of the stress created and provide a product which resists damage from thermal cycling without a perfect match in CTE between the metal substrate 26 and the substrate 18.

As stated above, the substrate 18 preferably contains a particulate filler, preferably inorganic, such as a mineral filler. The mineral filler can be glass fibers, talc, and/or magnesium hydroxide, preferably talc and/or magnesium hydroxide. Preferably, the substrate 18 comprises a thermoplastic polyolefin comprising a mineral filler. The substrate 18 has a CTE of between 25 ppm/deg C. and 50 ppm/deg C. (or any range within this range), preferably between 35 ppm/deg C. and 45 ppm/deg C. The mineral filler has a CTE which is less than that of the polymer of the substrate 18, and therefore reduces the CTE of the substrate 18 overall. Talc and magnesium hydroxide, for example, have a shape which permits the effects on CTE to be more isotropic than other fillers, such as glass fibers. During processing, such as extrusion or injection molding, glass fibers, for example, become oriented, resulting in an anisotropic effect on the CTE of the material to which they are added. For example, if the orientation occurs in the extrusion direction, the CTE in the extrusion direction would be higher than that of the direction transverse to the extrusion direction, resulting in an anisotropic CTE. Preferably, the substrate 18 comprises, by weight, 32% to 40% (or any range within this range) of the filler, preferably a mineral filler, such as talc and/or magnesium hydroxide.

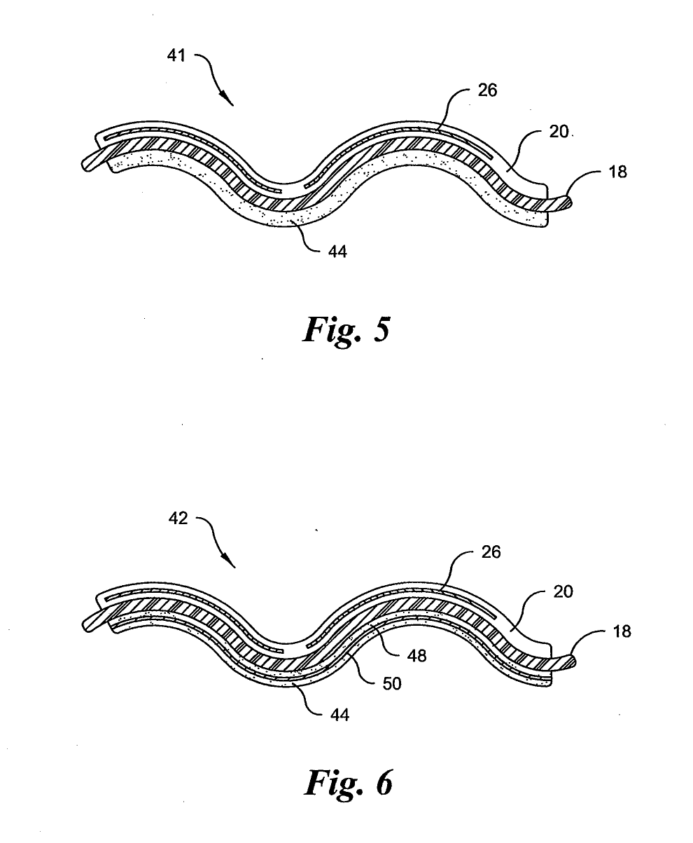

In reference to FIG. 5, the PV roofing tile 41 of the present embodiment can be configured to resemble conventional roofing tiles, such a curved or flat tiles, ceramic tiles, slate tiles, and the like. The PV roofing tile 41 can also include an optional insulation layer 44 on the backside (i.e., underside) of the PV roofing tile. Thus, the PV roofing tile would include the PV laminate 20 with the metal substrate 26 embedded in it, the substrate 18 in contact with the PV laminate 20, and optionally, an insulation layer 44 in contact with the substrate 18. However, other layers can be between the substrate 18 and the insulation layer 44.

Referring to FIG. 6, in another embodiment, the present invention provides for a second PV roofing tile 42 having the PV laminate 20, the substrate 18, and one or more layers on the substrate 18 which can be a second adhesive 48, a backing structure 50, and/or insulation 44. In this particular embodiment, the substrate 18 can be composed of any conventional polymer or other material readily known and used for PV roofing tiles. Thus, the CTE of the substrate 18 does not need to be adjusted, although it can be adjusted, if desired. Instead, the backing structure 50 is applied to the underside of the substrate 18 to provide for a balanced PV roofing tile structure. The backing structure 50 has a CTE that will help minimize the bending caused by differences in CTE between the substrate 18 and the metal substrate 26.

The backing structure 50 is adhered or otherwise secured to the underside of the substrate 18. Thus, the second adhesive 48 can be optionally used to adhere the backing structure 50 to the substrate 18, or to another layer between the substrate 18 and backing structure 50. The backing structure 50 can be, for example, a metal sheet, a polymeric rib having a metal portion or metal rods, a metal mesh, or a piece of metal sheet, configured to eliminate or minimize any bending moments caused by cyclic temperature variations. The backing structure 50 is configured to, preferably, have the same or comparable coefficient of thermal expansion as that of the metal substrate 26 on which the PV cells 24 are manufactured. However, merely sufficiently approaching the CTE of the metal substrate 26 will be advantageous. For example, the backing structure 50 may have a CTE between 25 ppm/deg C. and 50 ppm/deg C., although it is preferably lower and the range for the CTE can extend to 11 ppm/deg C. or even less, depending on the materials used. Preferably, the backing structure 50 is configured to be constructed of the same material as that of the metal substrate 26 so as to exhibit the same thermal expansion properties. However, any backing structure 50 having substantially the same or comparable coefficient of thermal expansion properties can be used in accordance with the present embodiment.

The backing structure 50 can be also be configured with additional polymeric or composite materials to further improve or minimize the amount of bending experienced by the PV roofing tile. Although a metal backing structure 50 is presently preferred, the backing structure 50 can be constructed out of any non-metal composition, such as a polymeric composition as described above, a composite material (e.g., a ceramic), or a combination thereof, that exhibits coefficient of thermal expansion properties comparable to those of the metal substrate 26 or at least which sufficiently approach those of the metal substrate 26.

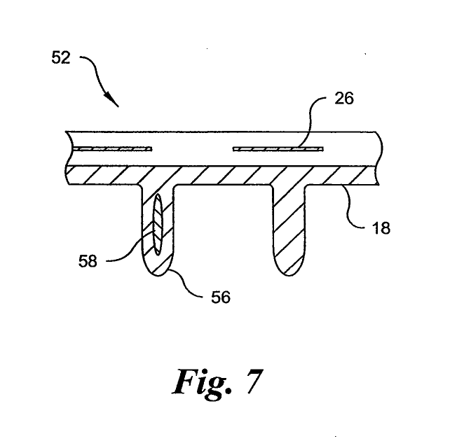

In reference to FIG. 7, the invention is directed to a third PV roofing tile 52. This third PV roofing tile 52 includes a substrate 18 having at least one rib 56. The rib 56 includes an insert 58 such as a metal rod, metal sheet, or member that traverses at least a portion of the length of the rib 56 to provide for a balanced roofing tile. The insert 58 preferably extends substantially along the width of the roofing tile 52 so as to maximize the balancing of the CTE and may extend across the entire width of the roofing tile 52. The insert 58 can be configured out of any material that provides for a comparable coefficient of thermal expansion as that of the metal substrate 26 or otherwise provides a CTE which is sufficiently close to that of metal substrate 26. The insert 58 is preferably inserted within the rib 56, but can alternatively be placed along the outside of the rib 56, or placed in any other configuration such that the rib 56 functions to maintain the insert 58 in proper positioning along the polymer 18. In FIG. 7, the substrate 18 is in contact with the metal substrate 26, although additional layers of material, such as polymeric layers, can be found between the metal substrate 26 and the substrate 18.

As described above, the PV roofing tiles with a balanced structure advantageously increase the durability of the PV roofing tile in the face of cyclic temperature variations when exposed to external environmental conditions. This is accomplished by reducing and even substantially matching the coefficient of thermal expansion properties of polymeric substrate 18 and/or backing structure 50 with that of the metal substrate 26.

### Example 1

A photovoltaic laminate with a back adhesive surface of 4% vinyl acetate (EVA) was compression bonded to a plaque of Solvay Sequel 1828. Solvay Sequel 1828 is a polypropylene co-polymer having a very low coefficient of linear thermal expansion. A sheet of Collano V764-2 was also placed between the laminate and plaque. Collano V764-2 is a modified polyolefin having a 75 g/m² coat weight layer. The compression bonding press was set to 140 degrees C. on both the top and bottom plates. A pressure of 30 psi was applied for 3 minutes. After compression bonding, the composite laminate was removed and allowed to cool.

To evaluate the effectiveness of the compression bonding process, the compression bonded composite part was thermally cycled 40 times from about −40 degrees C. to about 85 degrees C. No delamination was visually observed on the composite laminate after being exposed to thermal cycling.

The present invention minimizes the damage to the PV cells and improves the longevity of the PV roofing tiles by utilizing compression bonding to adhere the PV laminate 20 and the substrate 18 as well as by managing the CTE of the substrate 18 and/or the backing structure 50 so as to reduce delamination or other damage as a result of thermal cycling.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A method for producing a photovoltaic roofing tile, comprising the steps of:
(a) providing an open compression tool;
(b) placing an undulated formed polymeric substrate in the open compression tool;
(c) placing a substantially flat photovoltaic laminate in the open compression tool proximate the substrate; and
(d) applying heat and pressure to the photovoltaic laminate to bond the photovoltaic laminate with the substrate and to simultaneously impart undulations to the photovoltaic laminate which correspond to undulations in the substrate, wherein the applying heat and pressure comprises closing the compression tool to apply heat from the compression tool to the photovoltaic laminate and to compress the photovoltaic laminate and the substrate against one another.

2. The method according to claim 1, wherein step (b) comprises placing an undulated formed thermoplastic polyolefin substrate in the open compression tool.

3. The method according to claim 1, wherein step (b) comprises placing an undulated formed polymeric mineral-filled substrate in the open compression tool.

4. The method according to claim 1, wherein step (b) comprises placing an undulated formed polymeric substrate comprising at least one selected from the group consisting of talc and magnesium hydroxide fill therein in the open compression tool.

5. The method according to claim 1, wherein step (b) comprises:
(b)(1) priming an undulated formed polymeric substrate with flame treatment; and
(b)(2) placing the substrate in the open compression tool.

6. The method according to claim 1, wherein step (c) comprises placing a substantially flat photovoltaic laminate having a thermoplastic adhesive thereon for bonding to the substrate in the open compression tool.

7. The method according to claim 1, wherein step (c) comprises placing a substantially flat photovoltaic laminate comprising at least one selected from the group consisting of a modified polypropylene and a modified ethylene vinyl acetate thermoplastic adhesive thereon for bonding to the substrate, in the open compression tool.

8. The method according to claim 1, wherein step (c) comprises placing a substantially flat photovoltaic laminate comprising a photovoltaic layer structure having photovoltaic cells on a metal substrate, a backsheet layer structure in facing engagement with a first side of the photovoltaic layer structure, and a transparent layer in facing engagement with a second side of the photovoltaic layer structure, in the open compression tool.

9. The method according to claim 1, wherein step (c) comprises placing a substantially flat photovoltaic laminate comprising a photovoltaic layer structure having photovoltaic cells on a metal substrate, a backsheet layer structure in facing engagement with a first side of the photovoltaic layer structure, a transparent layer in facing engagement with a second side of the photovoltaic layer structure, and an adhesive layer in facing engagement with the backsheet layer structure, in the open compression tool.

10. The method according to claim 1, wherein step (c) comprises placing a substantially flat photovoltaic laminate comprising a photovoltaic layer structure having photovoltaic cells on a metal substrate, a first encapsulation layer on a first side of the photovoltaic layer structure, a tape layer structure on a second side of the photovoltaic layer structure, a second encapsulation layer on the tape layer structure, a backsheet layer structure on the first encapsulation layer, a tie layer on the backsheet layer structure, a fiberglass layer on the second encapsulation layer, and a transparent layer on the fiberglass layer, in the open compression tool.

11. The method according to claim 1, wherein step (c) comprises placing a substantially flat photovoltaic laminate comprising a photovoltaic layer structure having photovoltaic cells on a metal substrate, a first encapsulation layer comprising EVA on a first side of the photovoltaic layer structure, a tape layer structure comprising at least a three-layered structure including a layer of EVA, a layer of PET, and a layer of EVA on a second side of the photovoltaic layer structure, a second encapsulation layer comprising EVA on the tape layer structure, a backsheet layer structure comprising at least a three-layered structure having a layer of EVA, a layer of PET, and a layer of EVA on the first encapsulation layer, a tie layer comprising a thermoplastic hot melt on the backsheet layer structure, a fiberglass layer comprising nonwoven fiberglass on the second encapsulation layer, and a transparent layer comprising ETFE on the fiberglass layer, in the open compression tool.

12. The method according to claim 1, wherein step (d) comprises maintaining the compression tool at an operating temperature of 130 degrees C. to 160 degrees C. and applying 30 to 100 psi of pressure to the photovoltaic laminate.

13. A photovoltaic roof tile comprising a photovoltaic laminate and a polymeric substrate, wherein the substrate comprises a thermoplastic polyolefin comprising a mineral filler and having a CTE of between 25 ppm/deg C. and 50 ppm/deg C.

14. The photovoltaic tile according to claim 13, wherein the substrate has a CTE of between 35 ppm/deg C. and 45 ppm/deg C.

15. The photovoltaic tile according to claim 13, wherein the mineral filler comprises at least one selected from the group consisting of talc and magnesium hydroxide.

16. The photovoltaic tile according to claim 13, wherein the substrate comprises, by weight, 32% to 40% of the mineral filler.

17. The photovoltaic tile according to claim 13, wherein the photovoltaic laminate comprises a photovoltaic layer structure having photovoltaic cells on a metal substrate, a backsheet layer structure in facing engagement with a first side of the photovoltaic layer structure, a transparent layer in facing engagement with a second side of the photovoltaic layer structure, and an adhesive layer proximate the first side of the photovoltaic layer structure in facing engagement with the backsheet layer structure.

18. The photovoltaic tile according to claim 13, wherein the photovoltaic laminate comprises a photovoltaic layer structure having photovoltaic cells on a metal substrate, a first encapsulation layer on a first side of the photovoltaic layer structure, a tape layer structure on a second side of the photovoltaic layer structure, a second encapsulation layer on the tape layer structure, a backsheet layer structure on the first encapsulation layer, a tie layer on the backsheet layer structure, a fiberglass layer on the second encapsulation layer, and a transparent layer on the fiberglass layer.

19. The photovoltaic tile according to claim 18, wherein the tape layer structure comprises at least a three-layered structure having a layer of EVA, a layer of PET, and a layer of EVA, and wherein the first and second encapsulation layers comprise EVA, the backsheet layer structure comprises at least a three-layered structure having a layer of EVA, a layer of PET, and a layer of EVA, and wherein the tie layer comprises a thermoplastic hot melt, the fiberglass layer comprises a nonwoven fiberglass, and the transparent layer comprises ETFE.
